(19) United States
(12) Patent Application Publication
(10) Pub. No.: US 2010/0252734 A1
(43) Pub. Date: Oct. 7, 2010

(54) POWER SUPPLY FOR ELECTRON GUN AND ELECTRON MICROSCOPE HAVING THE SAME

(75) Inventors: Heung-Bok Kim, Gyeonggi-do (KR); Kyeong-Il Kwak, Gyeonggi-do (KR); Byung-Chul Jeon, Busan (KR); Jong-Hyun Kim, Gyeonggi-do (KR)

Correspondence Address: OHLANDT, GREELEY, RUGGIERO & PERLE, LLP, ONE LANDMARK SQUARE, 10TH FLOOR, STAMFORD, CT, 06901, US

(73) Assignee: SEC CO , LTD.

(21) Appl. No.: 12/675,855

(22) PCT Filed: Aug. 20, 2008
(86) PCT No.: PCT/KR2008/004831

§ 371 Date: Mar. 1, 2010

(30) Foreign Application Priority Data
Oct. 26, 2007 (KR) 10-2007-0108366

(51) Int. Cl. H01J 37/28; H01J 29/48

(52) U.S. Cl. 250/310; 315/379

(57) ABSTRACT

A power supply for supplying an electric power to an electron gun, which is used in an electron microscope, and an electron microscope having the same are disclosed. The power supply includes a base board, and at least one sub-board vertically mounted on the base board to supply an electric power to an anode electrode, a filament for emitting electrons, and a grid. The at least one sub-board can include a first sub-board to supply an accelerating voltage to the anode electrode, a second sub-board to supply a heating current to the filament, and a third sub-board to supply a grid voltage to the grid.

### TECHNICAL FIELD

The present invention relates to an electron microscope, and more particularly, to a power supply for supplying an electric power to an electron gun, which is used in an electron microscope, and an electron microscope having the same.

### BACKGROUND ART

Generally, an electron microscope is widely used in a field relative to a material science because it can observe a piece to be tested in a high magnification of, for example, more than several ten thousands ands and has a high depth of focus, as compared with an optic microscope.

Such an electron microscope usually includes an electron gun to generate electron beams, and an image pickup system to induce the electron beams generated from the electron gun to the piece to be tested and to obtain an image of the piece to be tested. The electron gun is provided with a cathode electrode, a filament to emit electrons, an anode electrode to accelerate the electrons emitted from filament, and a power supply to supply an electric power to the cathode electrode, the filament, and the enode electrode. The image pickup system is provided with first and second condenser lens to condense the electron beams generated and emitted from the electron gun to observe them in a predetermined magnification, a scanning coil to scan the electron beams in a predetermined area and a predetermined direction, and an aperture to allow the condensed electron beams to standardise and to reach the piece to be tested. According to the electron microscope having the construction as described above, when an heating current is supplied to the filament from the power supply to heat the filament, the filament emits electrons from an surface thereof. The electrons emitted from the filament is accelerated by the anode electrode to which an accelerating voltage is applied from the power supply. The accelerated electrons are adjusted in a proper size by the first and the second condenser lenses, and pass through the scanning coil and the aperture to scan on an surface of the piece to be tested. As a result, an information on a shape of the surface of the piece to be tested can be observed by a separate detecting and displaying unit, which detects and displays signals, such as secondary electrons, reflective electrons, etc., generated from the piece to be tested.

However, since the power supply of the conventional electron microscope has a structure in which electronic parts, such as transformers, high voltage condensers, high voltage diodes, etc., constituting the power supply are mounted on general panels and support rods, it is complicated in construction, and deteriorated in use efficiently for inner space. As a result, a problem occurs, in that the power supply is difficult to fabricate, increases in size and fabrication cost, and causes the electron microscope having the power supply to increase in entire size.

### DISCLOSURE

### Technical Problem

Exemplary embodiment of the present invention addresses at least the above problems and/or disadvantages and provide at least the advantages described below. Accordingly, an aspect of the present invention is to provide a power supply for supplying an electric power to an electron gun, which is capable of being easily fabricated and reducing a size and a fabrication cost, and an electron microscope having the same.

### Technical Solution

According to one aspect of an exemplary embodiment of the present invention, there is provided a power supply for supplying an electric power to an electron gun, including a base board, and at least one sub-board vertically mounted on the base board to supply the electric power to an anode electrode, a filament for emitting electrons, and a grid.

Here, the at least one sub-board may include a first sub-board to supply an accelerating voltage to the anode electrode, a second sub-board to supply a heating current to the filament, and a third sub-board to supply a grid voltage to the grid.

Heights of the first, the second, and the third sub-boards projected from the base board may be the same.

The first sub-board may include an accelerating voltage-generating circuit to generate the accelerating voltage, and an accelerating voltage-filtering circuit to remove a ripple from the accelerating voltage. At this time, the accelerating voltage-filtering circuit may be disposed in an unoccupied space formed in the vicinity of relatively small parts by differences in height between relatively large parts and the relatively small parts in the accelerating voltage-generating circuit.

The second sub-board may include a filament heating circuit to supply the heating current to the filament thus to heat the filament.

The third sub-board may include a grid voltage-generating circuit to generate the grid voltage, and a grid voltage-filtering circuit to remove a ripple from the grid voltage. At this time, the grid voltage-filtering circuit may be disposed in an unoccupied space formed in the vicinity of relatively small parts by differences in height between relatively large parts and the relatively small parts in the grid voltage-generating circuit.

According to another aspect of an exemplary embodiment of the present invention, there is provided an electron microscope, including an electron gun having a cathode electrode, a filament to emit an electron, a grid to accommodate the filament, an anode electrode to accelerate the electron emitted from the filament, and a power supply to supply an electric power to the cathode electrode, the filament, the grid, and the anode electrode, and an image pickup system having first and second condenser lens to condense an electron beam emitted from the electron gun, a scanning coil to scan the electron beam condensed by the first and the second condenser lens in a predetermined direction and an predetermined area, and aperture to standardize the electron beam scanned by the scanning coil and to allow the electron beam to reach a piece to be tested. The power supply includes a base board, and at least one sub-board vertically mounted on the base board to supply the electric power to the anode electrode, the filament and the grid.

Here, the at least one sub-board may include a first sub-board to supply an accelerating voltage to the anode electrode, a second sub-board to supply a heating current to the filament, and a third sub-board to supply a grid voltage to the grid.

The first sub-board may include an accelerating voltage-generating circuit to generate the accelerating voltage, and an accelerating voltage-filtering circuit to remove a ripple from the accelerating voltage.

The second sub-board may include a filament heating circuit to supply the heating current to the filament thus to heat the filament.

The third sub-board may include a grid voltage-generating circuit to generate the grid voltage, and a grid voltage-filtering circuit to remove a ripple from the grid voltage.

### ADVANTAGEOUS EFFECTS

The power supply for supplying the electric power to the electron gun according to the exemplary embodiment of the present invention is configured, so that the first, the second, and the third sub-boards in which the electronic part are mounted, respectively, are vertically mounted on the base board. Accordingly, the power supply according to the exemplary embodiment of the present invention is simplified in construction and reduced in volume, as compared with the conventional power supply in which the electronic parts are mounted on the general panels and the supporting rods. In addition, as the first, the second, and the third sub-boards mounted on the base board are configured so that the heights of the first, the second, and the third sub-boards projected from the base board are the same, it prevents a loss in space and an increase in volume from being generated due to differences between the heights of the first, the second, and the third sub-boards. Also, as the circuits constituting the first, the second, and the third sub-boards are arranged so that at least one circuit is disposed in an space in which the electronic parts constituting adjacent other circuits are unoccupied, for example, an vacant space formed in the vicinity of relatively small parts of the adjacent other circuits by differences in height between relatively large parts and the relatively small parts of the adjacent other circuits, conforming to heights of the electronic parts of the adjacent other circuits, the power supply according to the exemplary embodiment of the present invention prevents an increase in volume from being generated as the relatively small parts of the circuits are assigned to have unnecessary mounting space an much as the differences in height between the relatively small parts and the relatively large parts of the circuits. As a result, the power supply according to the exemplary embodiment of the present invention and the electron microscope having the same can be easily fabricated, and reduce a size and a fabrication cost.

### BRIEF DESCRIPTION OF THE DRAWINGS

FIG. 1 is a schematic block diagram exemplifying an electron microscope to which a power supply for supplying an electric power to an electron gun according to an exemplary embodiment of the present invention is applied,

FIG. 2 is a perspective view exemplifying a casing of the power supply shown in FIG. 1,

FIG. 3 is a top plan view exemplifying a base board and first, second and third sub-boards mounted on the base board of the power supply shown in FIG. 2,

FIG. 4 is a top plan view exemplifying the base board of the power supply shown in FIG. 3,

FIG. 5 is a front view exemplifying an accelerating voltage-generating circuit of the first sub-board of the power supply shown in FIG. 3,

FIG. 6 is a front view exemplifying an accelerating voltage-filtering circuit of the first sub-board of the power supply shown in FIG. 3,

FIG. 7 is a front view exemplifying a filament heating circuit of the second sub-board of the power supply shown in FIG. 3,

FIG. 8 is a front view exemplifying a grid voltage-generating circuit of the third sub-board of the power supply shown in FIG. 3, and

FIG. 9 is a front view exemplifying a grid voltage-filtering circuit of the third sub-board of the power supply shown in FIG. 3.

### BEST MODEL

Hereinafter, a power supply for supplying an electric power to an electron gun according to an exemplary embodiment of the present invention and an electron microscope having the same will now be described in greater detail with reference to the accompanying drawings.

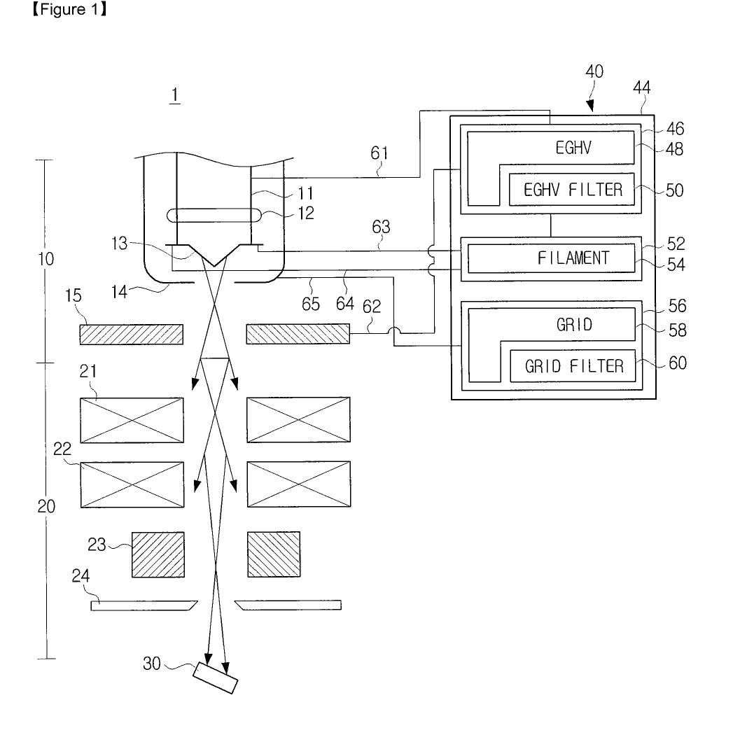

FIG. 1 is a schematic block diagram exemplifying an scanning electron microscope to which the power supply for supplying the electric power to the electron gun according to the exemplary embodiment of the present invention is applied.

As shown in FIG. 1, the scanning electron microscope 1 includes an electron gun 10 and an image pickup system 20.

The electron gun 10, which generates electron beams, includes a cathode electrode 11, a filament 13 made of a metal, such as a tungsten, to emit electrons, a grid 14 to accommodate the filament 13, an anode electrode 15 to accelerate the electrons emitted from the filament 13, and a power supply 40 for supplying an electric power to the cathode electrode 11, the filament 13, the grid 14 and the anode electrode 15.

The cathode electrode 11, the filament 13, the grid 14 and the anode electrode 15 except for the power supply 40 are contained in a cylindrical column (not shown), and have the same construction as known in the art. Accordingly, a detailed explanation on constructions of the cathode electrode 11, the filament 13, the grid 14 and the anode electrode 15 will be omitted.

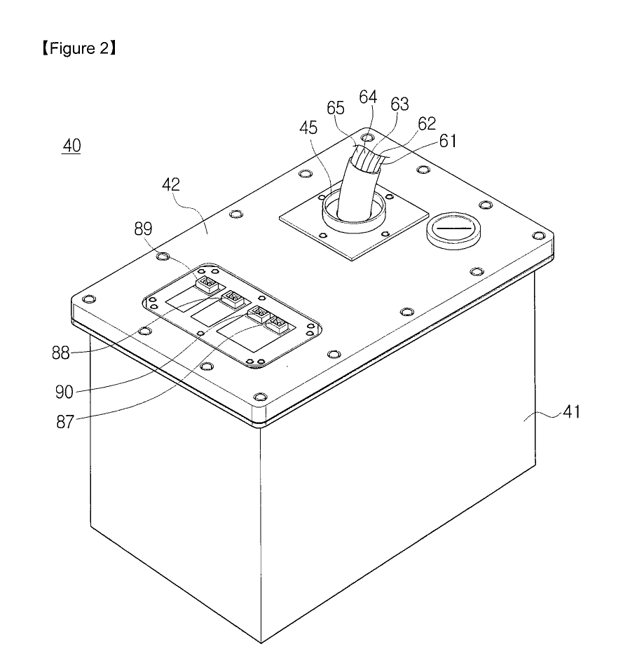

The power supply 40 is provided with a base board 44, a first sub-board 46, a second sub-board 52, a third sub-board 56, and a casing 41 (see FIG. 2).

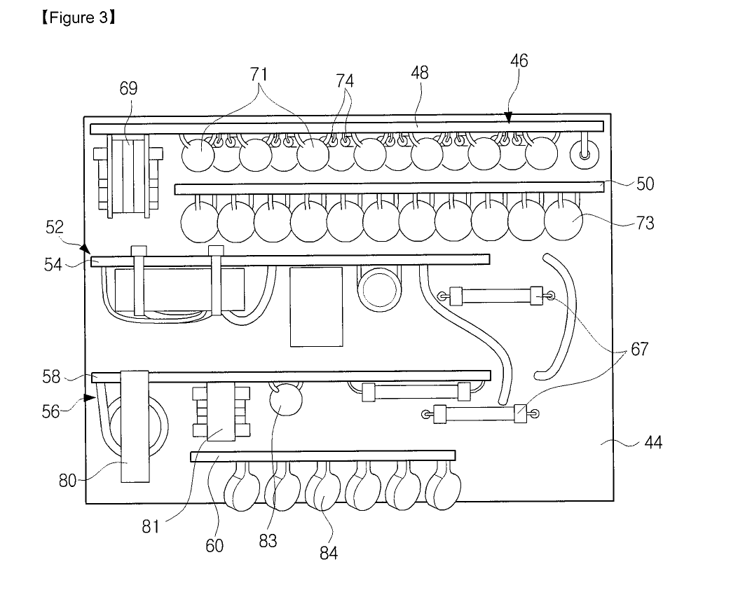

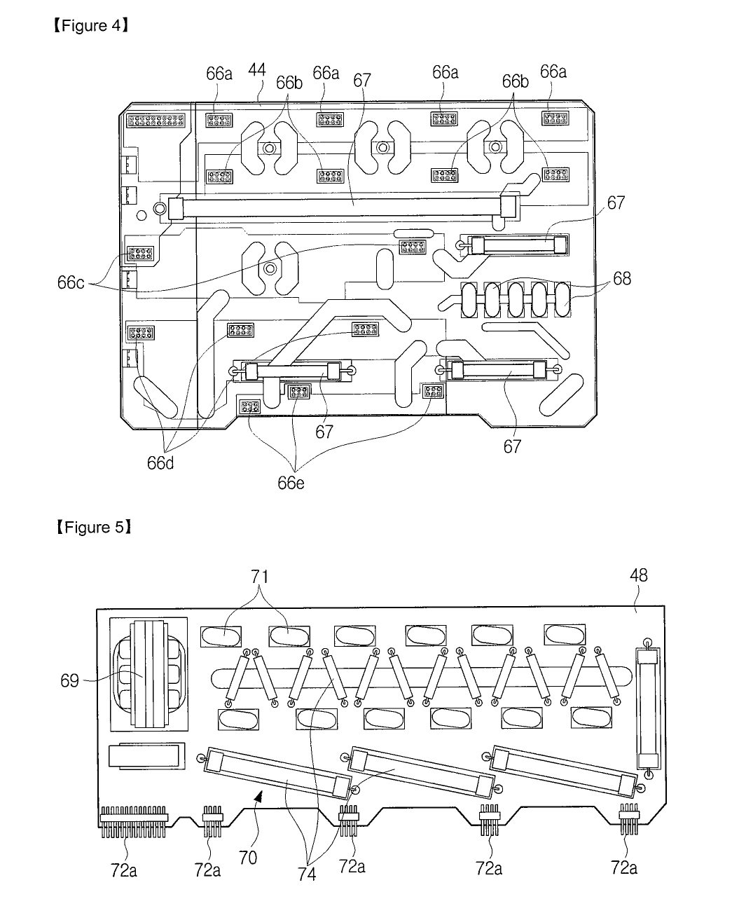

As shown in FIG. 3, the first, the second and the third sub-board 46, 52 and 56, which have almost the same height, are vertically mounted on the base board 44. For this, as shown in FIG. 4, first through fifth terminal grooves 66a, 66b, 66c, 66d, and 66e are formed on the base board 44, so that they can accommodate and join first through fifth connecting terminals 72a, 72b, 72c, 72d and 72c formed at lower parts of corresponding circuits 48, 50, 54, 58 and 60 of the first, the second and the third sub-board 46, 52 and 56. Also, a plurality of high voltage resistors 67 and a plurality of high voltage condensers 68 are mounted on the base board 44. The high voltage resistors 67 function to transmit signals, that is, voltages, between the first, the second and the third sub-board 46, 52 and 56, and the high voltage condensers 68 function to filter the voltages and to transform the voltages into direct currents.

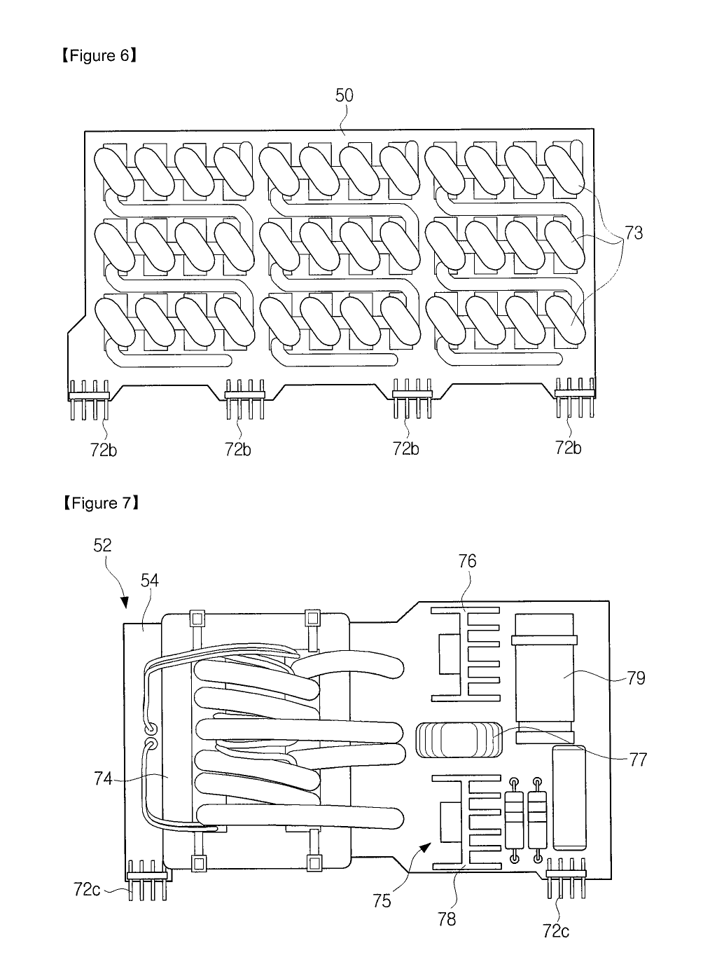

The first sub-board 46, which applies an accelerating voltage of, for example, about 30 kV, to the anode electrode 15, includes an accelerating voltage-generating circuit 48 to generate an accelerating voltage, and an accelerating voltage-filtering circuit 50 to remove a ripple from the accelerating voltage. As shown in FIG. 5, the accelerating voltage-generating circuit 48 is made up of a circuit board in which a transformer 69 and a voltage multiplication circuit 70 are mounted. The transformer 69 transforms an input voltage into an voltage of about 5,000V, and the voltage multiplication circuit 70 raises the voltage of about 5,000V to 30 kV. The voltage multiplication circuit 70 is made up of a plurality of high voltage diodes 74 and a plurality of high voltage condensers 71. Also, a plurality of first connecting terminals 72a, which is inserted into and connected to the first terminal groove 66a of the base board 44, is projected from the lower part of the accelerating voltage-generating circuit 48. According to this, the accelerating voltage-generating circuit 48 is vertically mounted on the base board 44. As shown in FIG. 6, the accelerating voltage-filtering circuit 50 is made up of a circuit board having a plurality of high voltage condensers 73 to remove the ripple from the accelerating voltage of about 30 kV and thus to stabilize an output. A plurality of second connecting terminals 72b, which is inserted into and connected to the second terminal groove 66b of the base board 44, is projected from the lower part of the accelerating voltage-filtering circuit 50, and thereby the accelerating voltage-filtering circuit 50 is vertically mounted on the base board 44. At this time, to reduce the power supply 40 in size, as shown in FIG. 3, the accelerating voltage-filtering circuit 50 is arranged, so that it is disposed in an vacant space formed by a large size or height of part, for example, the transformer 69, of the accelerating voltage-generating circuit 48 in front of a small size or height of parts, for example, the high voltage diodes 74 and the high voltage condensers 71, of the accelerating voltage-generating circuit 48.

The second sub-board 52, which heats the filament 13 to emit the electrons, includes a filament heating circuit 54. The filament heating circuit 54 applies an heating current of, for example, 2.5 A to 3 A, to the filament 13 to heat the filament 13. As shown in FIG. 7, the filament heating circuit 54 is made up of a circuit board on which an insulating transformer 74 and a rectification circuit 75 are mounted. The insulating transformer 74 maintains an voltage of the filament heating circuit 54 in the range of 30 kV, and the rectification circuit 75 rectifies the heating current. The rectification circuit 75 is provided with a diode 76 to rectify the heating current, a condenser 79 to filter a ripple from the heating current, a filter 77 to attenuate the ripple from heating current, a filament output rectifier 78 to rectify the heating current outputted to the filament 13, etc. To vertically mount the filament heating circuit 54 on the base board 44, a plurality of third connecting terminals 72c, which is inserted into and connected to the third terminal groove 66c of the base board 44, is projected from the lower part of the filament heating circuit 54.

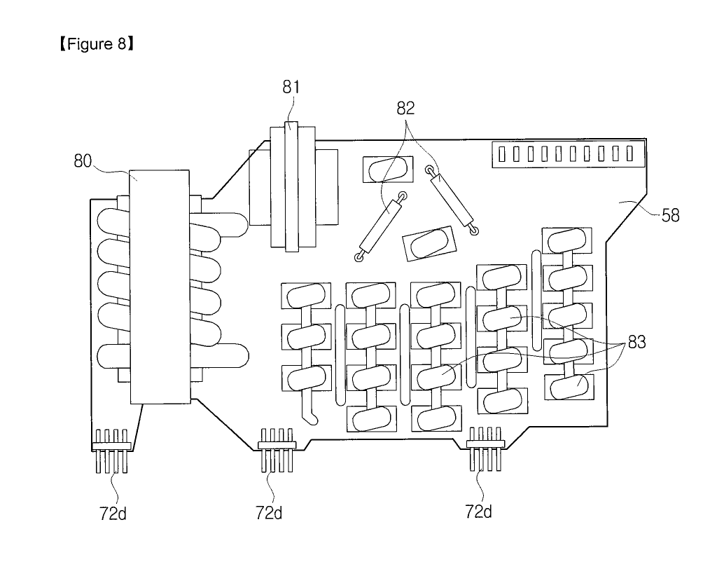

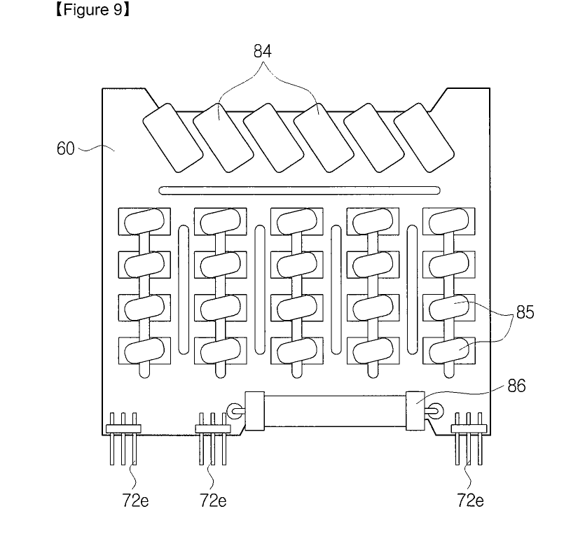

The third sub-board 56, which applies a grid voltage of, for example, 30,300V to 30,800V, to the grid 14 and thus controls an amount of electrons generated from the filament 13, includes a grid voltage-generating circuit 58 to generate the grid voltage, and a grid voltage-filtering circuit 60 to remove a ripple from the grid voltage. As shown in FIG. 8, the grid voltage-generating circuit 58 is made up of a circuit board in which an insulating transformer 80, a voltage raising transformer 81, a plurality of high voltage condensers 83, and a high voltage diode 82 are mounted, and produces the grid voltage of 30,300V to 30,800V. The insulating transformer 80 maintains an voltage of the grid voltage-generating circuit 58 in the range of about 30 kV. The voltage raising transformer 81 raises an input voltage to about 5,000V. The plurality of high voltage condensers 83 divides the voltage raised to about 5,000V. The high voltage diode 82 rectifies the voltage. A plurality of fourth connecting terminals 72d, which is inserted into and connected to the fourth terminal groove 66d of the base board 44, is projected from the lower part of the grid voltage-generating circuit 58. According to this, the grid voltage-generating circuit 58 is vertically mounted on the base board 44. As shown in FIG. 9, the grid voltage-filtering circuit 60 is made up of a circuit board on which a plurality of high voltage condensers 84, a plurality of high voltage diodes 85 and a high voltage resister 86 are mounted to remove the ripple from the grid voltage produced by the grid voltage-generating circuit 58. A plurality of fifth connecting terminals 72e, which is inserted into and connected to the fifth terminal groove 66e of the base board 44, is projected from the lower part of the grid voltage-filtering circuit 60, and thereby the grid voltage-filtering circuit 60 is vertically mounted on the base board 44. At this time, to reduce the power supply 40 in size, as shown in FIG. 3, the grid voltage-filtering circuit 60 is arranged, so that it is disposed in an vacant space formed by a large size or height of part, for example, the insulating transformer 80, of the grid voltage-generating circuit 58 in front of a small size or height of parts, for example, the transformer 81, the high voltage diodes 82 and the high voltage condensers 83, of the grid voltage-generating circuit 58.

As shown in FIG. 2, the casing 41, which contains the base board 44 having the first, the second and the third sub-boards 46, 52, and 56 mounted thereon, is formed in the form of a rectangular box having an opened top. The casing 41 at the top thereof is closed up by a cover 42 by using of fixing means, such as screws, etc. On the cover 42 are formed a cable hole part 45, power connecting sockets 87, 88 and 89, and a voltage/voltage monitoring socket 90. The cable hole part 45 guides cables 61, 62, 63, 64 and 65 connected to the first, the second and the third sub-boards 46, 52, and 56 to draw out to the outside of the casing 41, so that the cables 61, 62, 63, 64 and 65 can be connected to the cathode electrode 11, the filament 13 and the anode electrode 15 of the electron gun 10. Corresponding sockets (not shown) of outer power cables are connected to the power connecting sockets 87, 88 and 89, and the power connecting sockets 87, 88 and 89 are connected to the first, the second and the third sub-boards 46, 52, and 56 through the base board 44 in the casing 41 so as to supply the electric power to the first, the second and the third sub-boards 46, 52, and 56. A corresponding socket (not shown) of a voltage/voltage monitoring cable connected to an outer controller (not shown), such as a personal computer, is connected to the voltage/voltage monitoring socket 90, and the voltage/voltage monitoring socket 90 is connected to the first sub-board 46 through the base board 44 in the casing 41 so as to transmit voltage and current signals of the first sub-board 46 to the outer controller.

Referring again to FIG. 1, the image pickup system 20, which induces the electron beam generated from the electron gun 10 to a piece 30 to be tested and obtains an image of the piece 30 to be tested, is provided with first and second condenser lens 21 and 22. The first and the second condenser lens 21 and 22 condense the electron beam generated and emitted from the electron gun 10 in a minute electron probe in a diameter of 3-100 nm, so that the electron beam can be observed in a predetermined magnification. The condensed electron probe is scanned by a scanning coil 23 in an area newly set in a two-dimensional direction of X and Y on an surface of the electron. The electron probe scanned by the scanning coil 23 is standardized while passing through an aperture 24, and then reaches the piece 30 to be tested. Signals, such as secondary electrons, reflective electrons, etc., generated from the piece 30 to be tested are detected and displayed by a detecting and displaying unit (not shown).

As described above, the power supply 40 of the electron microscope 1 in accordance with the exemplary embodiment of the present invention is configured, so that the first, the second and the third sub-boards 46, 52 and 56 made up of the circuits having the electronic parts mounted thereon, respectively, are vertically mount on the base board 44. Accordingly, the power supply according to the exemplary embodiment of the present invention is simplified in construction and reduced in volume, as compared with the conventional power supply in which the electronic parts are mounted on the general panels and the supporting rods. In addition, as the first, the second, and the third sub-boards 46, 52 and 56 mounted on the base board 44 are configured so that the heights thereof projected from the base board 44 are the same, the power supply 40 according to the exemplary embodiment of the present invention prevents a loss in space and an increase in volume from being generated due to the differences between the heights of the first, the second, and the third sub-boards 46, 52 and 56. Also, as the circuits 48, 50, 54, 58 and 60 constituting the first, the second, and the third sub-boards 46, 52 and 56 are arranged so that at least one circuit 50 and/or 60 is disposed conforming to heights of the electronic parts of the adjacent other circuits 48 and/or 58, for example, in the vacant space formed in the vicinity of relatively small parts 71 and 74; and/or 81 and 83 of the adjacent other circuits 48 and/or 58 by the differences in height between the relatively small parts 71 and 74; and/or 81 and 83 and relatively large parts 69 and/or 80 of the adjacent other circuits 48 and/or 58, the power supply 40 according to the exemplary embodiment of the present invention prevents an increase in volume from being generated as the relatively small parts 71 and 74; and/or 81 and 83 of the circuits 48 and/or 58 are assigned to have unnecessary mounting space an much as the differences in height between the relatively small parts 71 and 74; and/or 81 and 83 and the relatively large parts 69 and/or 80 of the circuits 48 and/or 58. As a result, the power supply 40 according to the exemplary embodiment of the present invention and the electron microscope 1 having the same can be easily fabricated, and reduce a size and a fabrication cost.

According to a power supply 40 actually fabricated in accordance with the exemplary embodiment of the present invention, a size of the power supply 40 has been reduced by two-thirds as compared with that of the conventional power supply.

Since an operation of the electron microscope 1 having the power supply 40 constructed as described above is the same as that of the conventional electron microscope known in the art, a detailed description thereof will be omitted.

Although representative embodiment of the present invention has been shown and described in order to exemplify the principle of the present invention, the present invention is not limited to the specific exemplary embodiment. It will be understood that various modifications and changes can be made by one skilled in the art without departing from the spirit and scope of the invention as defined by the appended claims. Therefore, it shall be considered that such modifications, changes and equivalents thereof are all included within the scope of the present invention.

1. A power supply for supplying an electric power to an electron gun, comprising:
a base board;
at least one sub-board vertically mounted on the base board to supply the electric power to an anode electrode, a filament for emitting electrons, and a grid;
a casing containing the base board having the at least one sub-board mounted thereon, and having an opened top; and
a cover closing the top of the casing and having a cable hole part formed to guide cables connected to the at least one sub-board to draw out to the outside of the casing, power connecting sockets connected to corresponding sockets of outer power cables and connected with the at least one sub-board through the base board in the casing, and a voltage/voltage monitoring socket connected to a corresponding socket of a voltage/voltage monitoring cable connected to an outer controller and connected to the at least one sub-board through the base board in the casing.

2. The power supply as claimed in claim 1, wherein the at least one sub-board comprises:
a first sub-board to supply an accelerating voltage to the anode electrode;
a second sub-board to supply a heating current to the filament; and
a third sub-board to supply a grid voltage to the grid.

3. The power supply as claimed in claim 2, wherein heights of the first, the second, and the third sub-boards projected from the base board are the same.

4. The power supply as claimed in claim 2, wherein the first sub-board comprises:
an accelerating voltage-generating circuit to generate the accelerating voltage; and
an accelerating voltage-filtering circuit to remove a ripple from the accelerating voltage.

5. The power supply as claimed in claim 4, wherein the accelerating voltage-filtering circuit is disposed in an unoccupied space formed in the vicinity of relatively small parts by differences in height between relatively large parts and the relatively small parts in the accelerating voltage-generating circuit.

6. The power supply as claimed in claim 2, wherein the second sub-board comprises a filament heating circuit to supply the heating current to the filament thus to heat the filament.

7. The power supply as claimed in claim 2, wherein the third sub-board comprises:
a grid voltage-generating circuit to generate the grid voltage; and
a grid voltage-filtering circuit to remove a ripple from the grid voltage.

8. The power supply as claimed in claim 7, wherein the grid voltage-filtering circuit is disposed in an unoccupied space formed in the vicinity of relatively small parts by differences in height between relatively large parts and the relatively small parts in the grid voltage-generating circuit.

9. An electron microscope, comprising:
an electron gun having a cathode electrode, a filament to emit an electron, a grid to accommodate the filament, an anode electrode to accelerate the electron emitted from the filament, and a power supply to supply an electric power to the cathode electrode, the filament, the grid, and the anode electrode; and
an image pickup system having first and second condenser lens to condense an electron beam emitted from the electron gun, a scanning coil to scan the electron beam condensed by the first and the second condenser lens in a predetermined direction and an predetermined area, and aperture to standardize the electron beam scanned by the scanning coil and to allow the electron beam to reach a piece to be tested,
wherein the power supply comprises:
a base board;
at least one sub-board vertically mounted on the base board to supply the electric power to the anode electrode, the filament and the grid;
a casing containing the base board having the at least one sub-board mounted thereon, and having an opened top; and
a cover closing the top of the casing and having a cable hole part formed to guide cables connected to the at least one sub-board to draw out to the outside of the casing, power connecting sockets connected to corresponding sockets of outer power cables and connected with the at least one sub-board through the base board in the casing, and a voltage/voltage monitoring socket connected to a corresponding socket of a voltage/voltage monitoring cable connected to an outer controller and connected to the at least one sub-board through the base board in the casing.

10. The electron microscope as claimed in claim 9, wherein the at least one sub-board comprises:
a first sub-board to supply an accelerating voltage to the anode electrode;
a second sub-board to supply a heating current to the filament; and
a third sub-board to supply a grid voltage to the grid.

11. The electron microscope as claimed in claim 10, wherein the first sub-board comprises:
an accelerating voltage-generating circuit to generate the accelerating voltage; and
an accelerating voltage-filtering circuit to remove a ripple from the accelerating voltage.

12. The electron microscope as claimed in claim 10, wherein the second sub-board comprises a filament heating circuit to supply the heating current to the filament thus to heat the filament.

13. The electron microscope as claimed in claim 10, wherein the third sub-board comprises:
a grid voltage-generating circuit to generate the grid voltage; and
a grid voltage-filtering circuit to remove a ripple from the grid voltage.

14. A power supply for supplying an electric power to an electron gun, comprising:
a base board; and
at least one sub-board vertically mounted on the base board to supply the electric power to an anode electrode, a filament for emitting electrons, and a grid,
wherein the at least one sub-board comprises an accelerating voltage-generating circuit to generate an accelerating voltage; and an accelerating voltage-filtering circuit to remove a ripple from the accelerating voltage,
wherein the accelerating voltage-filtering circuit is disposed in an unoccupied space formed in the vicinity of relatively small parts by differences in height between relatively large parts and the relatively small parts in the accelerating voltage-generating circuit, and
wherein the accelerating voltage-filtering circuit and the accelerating voltage-generating circuit are arranged parallel to each other.

15. An electron microscope, comprising:
an electron gun having a cathode electrode, a filament to emit an electron, a grid to accommodate the filament, an anode electrode to accelerate the electron emitted from the filament, and a power supply to supply an electric power to the cathode electrode, the filament, the grid, and the anode electrode; and
an image pickup system having first and second condenser lens to condense an electron beam emitted from the electron gun, a scanning coil to scan the electron beam condensed by the first and the second condenser lens in a predetermined direction and an predetermined area, and aperture to standardize the electron beam scanned by the scanning coil and to allow the electron beam to reach a piece to be tested,
wherein the power supply comprises a base board; and at least one sub-board vertically mounted on the base board to supply the electric power to the anode electrode, the filament and the grid,
wherein the at least one sub-board comprises an accelerating voltage-generating circuit to generate an accelerating voltage; and an accelerating voltage-filtering circuit to remove a ripple from the accelerating voltage, wherein the accelerating voltage-filtering circuit is disposed in an unoccupied space formed in the vicinity of relatively small parts by differences in height between relatively large parts and the relatively small parts in the accelerating voltage-generating circuit, and
wherein the accelerating voltage-filtering circuit and the accelerating voltage-generating circuit are arranged parallel to each other.
